(19) United States
(12) Patent Application Publication
(10) Pub. No.: US 2023/0395639 A1
(43) Pub. Date: Dec. 7, 2023

(54) IMAGE SENSOR WITH ENHANCED MULTI-SUBSTRATE STRUCTURES AND INTERCONNECTS

(71) Applicant: Samsung Electronics Co., Ltd., Suwon-si (KR)

(72) Inventors: Doo Won Kwon, Seongnam-si (KR); In Gyu Baek, Seoul (KR)

(21) Appl. No.: 18/450,730

(22) Filed: Aug. 16, 2023

Related U.S. Application Data
(63) Continuation of application No. 16/837,299, filed on Apr. 1, 2020.

(30) Foreign Application Priority Data
Aug. 8, 2019 (KR) 10-2019-0096506

(51) Int. Cl. H01L 27/146; H01L 23/00

(52) U.S. Cl. CPC H01L 27/14636; H01L 24/05; H01L 27/14605

(57) ABSTRACT

An image sensor includes a first substrate structure, which includes a first substrate having a photoelectric converter and a first wiring structure therein. The first wiring structure includes upper connection wiring, which is electrically connected to the photoelectric converter, a first upper bonding pad and a second upper bonding pad. A second substrate structure is provided, which includes a second substrate and a second wiring structure bonded to the first wiring structure. The second wiring structure includes: lower connection wiring, which is electrically connected to the upper connection wiring, a first lower bonding pad, which is directly connected to the first upper bonding pad, and a second lower bonding pad, which is directly connected to the second upper bonding pad. A width of the first upper bonding pad is unequal to a width of the second upper bonding pad, and a thickness of the first upper bonding pad is unequal to a thickness of the second upper bonding pad.

### REFERENCE TO PRIORITY APPLICATION

This application claims priority to U.S. patent application Ser. No. 16/837,299, Apr. 1, 2020, which claims the benefit of Korean Patent Application No. 10-2019-0096506, filed Aug. 8, 2019, the disclosures of which are hereby incorporated herein by reference in their entirety.

### BACKGROUND

The present disclosure relates to image sensors and, more particularly, to image sensors with stacked structures.

An image sensor is a device that converts an optical image into an electrical signal. Image sensors may be classified into charge coupled device (CCD) image sensors and complementary metal oxide semiconductor (CMOS) image sensors (CIS). A CIS includes a plurality of pixels arranged in two dimensions. Each of the pixels can include a respective photodiode, which converts incident light into an electrical signal.

Recently, with the development of computer and communication industries, the demand for image sensors with enhanced performance has been increasing in various fields such as digital cameras, camcorders, personal communication systems, game devices, security cameras, micro-cameras for medical use, and robots, for example. In addition, image sensors are becoming more highly integrated as semiconductor devices become more highly integrated.

### SUMMARY

Aspects of the present disclosure provide image sensors that can be minimized and improved in image processing speed through direct bonding of stacked upper and lower structures.

The above and other aspects of the present disclosure will become more apparent to one of ordinary skill in the art to which the present disclosure pertains by referencing the detailed description of the present disclosure given below.

According to an aspect of the present disclosure, there is provided an image sensor including a first substrate structure, which includes a first substrate having a photoelectric converter and a first wiring structure, and a second substrate structure, which includes a second wiring structure bonded to the first wiring structure and a second substrate. The first wiring structure includes an upper connection wiring electrically connected to the photoelectric converter, a first upper bonding pad and a second upper bonding pad. The second wiring structure includes a lower connection wiring electrically connected to the upper connection wiring, a first lower bonding pad directly connected to the first upper bonding pad and a second lower bonding pad directly connected to the second upper bonding pad. A first width of the first upper bonding pad is greater than a second width of the second upper bonding pad, and a first thickness of the first upper bonding pad is greater than a second thickness of the second upper bonding pad.

According to another aspect of the present disclosure, there is provided an image sensor including a first substrate structure which includes a first substrate and a first wiring structure, and a second substrate structure which includes a second wiring structure bonded to the first wiring structure and a second substrate having a logic circuit electrically connected to a photoelectric converter. The first substrate includes a pixel region having the photoelectric converter and a first connection region, the first wiring structure includes an upper connection wiring electrically connected to the photoelectric converter, a first upper bonding pad connected to the upper connection wiring and a second upper bonding pad. The second wiring structure includes a first lower bonding pad directly connected to the first upper bonding pad, a second lower bonding pad directly connected to the second upper bonding pad and a lower connection wiring connected to the first lower bonding pad. In some embodiments, the first upper bonding pad overlaps the first connection region, the second upper bonding pad overlaps the pixel region, a first width of the first upper bonding pad is greater than a second width of the second upper bonding pad, and a first thickness of the first upper bonding pad is greater than a second thickness of the second upper bonding pad.

According to another aspect of the present disclosure, there is provided an image sensor including a first substrate which includes a pixel region and a connection region, a color filter and a microlens, which are disposed on a first surface of the first substrate, and a first wiring structure, which is disposed on a second surface of the first substrate facing the first surface of the first substrate. A second substrate is provided, which has a logic circuit electrically connected to a photoelectric converter formed in the pixel region, and a second wiring structure which is disposed between the second substrate and the first wiring structure and is bonded to the first wiring structure. The first wiring structure includes an upper connection wiring electrically connected to the photoelectric converter, a first upper bonding pad connected to the upper connection wiring and a second upper bonding pad. The second wiring structure includes a first lower bonding pad directly connected to the first upper bonding pad, a second lower bonding pad directly connected to the second upper bonding pad and a lower connection wiring connected to the first lower bonding pad and the logic circuit. The first upper bonding pad overlaps the connection region, the second upper bonding pad overlaps the pixel region, a first width of the first upper bonding pad is greater than a second width of the second upper bonding pad, a first thickness of the first upper bonding pad is greater than a second thickness of the second upper bonding pad, and a third thickness of the first lower bonding pad is greater than a fourth thickness of the second lower bonding pad.

### BRIEF DESCRIPTION OF THE DRAWINGS

These and/or other aspects will become apparent and more readily appreciated from the following description of the embodiments, taken in conjunction with the accompanying drawings in which:

FIG. 1 is a block diagram of an image sensor according to embodiments;

FIG. 2 is a circuit diagram of a unit pixel of the image sensor according to the embodiments;

FIG. 3 is a schematic layout view of the image sensor according to the embodiments;

FIG. 4 is a schematic cross-sectional view of an image sensor according to embodiments;

FIG. 5 is an enlarged view of portion X of FIG. 4;

FIG. 6 is an enlarged view of portion Y of FIG. 4;

FIG. 7 illustrates an image sensor according to embodiments;

FIG. 8 illustrates an image sensor according to embodiments;

FIG. 9 illustrates an image sensor according to embodiments;

FIG. 10 illustrates an image sensor according to embodiments;

FIG. 11 illustrates an image sensor according to embodiments;

FIG. 12 illustrates an image sensor according to embodiments;

FIG. 13 is a schematic layout view of an image sensor according to embodiments;

FIG. 14 is a schematic cross-sectional view of an image sensor according to embodiments; and

FIG. 15 is an enlarged view of portion Y of FIG. 14.

### DETAILED DESCRIPTION

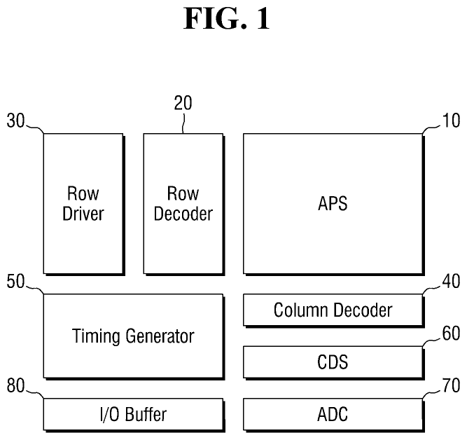

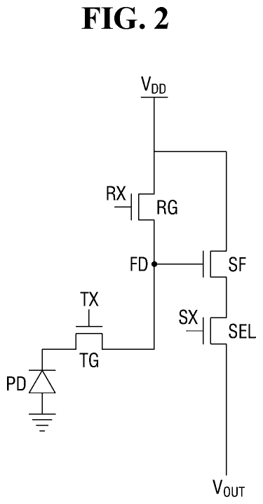

FIG. 1 is a block diagram of an image sensor according to embodiments and FIG. 2 is a circuit diagram of a unit pixel of the image sensor according to the embodiments. Referring to FIG. 1, the image sensor according to the embodiments includes an active pixel sensor (APS) array 10, a row decoder 20, a row driver 30, a column decoder 40, a timing generator 50, a correlated double sampler (CDS) 60, an analog-to-digital converter (ADC) 70, and an input/output (I/O) buffer 80.

The APS array 10 may include a plurality of unit pixel regions arranged in two dimensions. The APS array 10 may convert optical signals into electrical signals. The APS array 10 may be driven by a plurality of driving signals such as a pixel selection signal, a reset signal, and a charge transfer signal received from the row driver 30. In addition, the electrical signals output from the APS array 10 may be provided to the CDS 60. The row driver 30 may provide a plurality of driving signals for driving a plurality of unit pixel regions to the APS array 10 according to the decoding result of the row decoder 20. When the unit pixel regions are arranged in a matrix, the driving signals may be provided to each row. The timing generator 50 may provide a timing signal and a control signal to the row decoder 20 and the column decoder 40. The CDS 60 may receive the electrical signals generated by the APS array 10 and hold and sample the received electrical signals. The CDS 60 may double-sample a specific noise level and signal levels of the electrical signals and output difference levels between the noise level and the signal levels. The ADC 70 may convert analog signals corresponding to the difference levels output from the CDS 60 into digital signals and output the digital signals. The I/O buffer 80 may latch the digital signals and sequentially output the latched signals to an image signal processor according to the decoding result of the column decoder 40.

Referring to FIG. 2, a pixel circuit according to embodiments may be a circuit that generates an electrical signal using charges generated by a photoelectric converter PD. The pixel circuit is illustrated as a 4T circuit including four transistors, but embodiments are not limited to this case. The pixel circuit may include a transfer transistor TG, a floating diffusion region FD, a reset transistor RG, a source follower transistor SF, and a selection transistor SEL. The photoelectric converter PD may absorb light and accumulate charges corresponding to the amount of light. The photoelectric converter PD may be, but is not limited to, a semiconductor photodiode, a phototransistor, a photogate, or a pinned photodiode. The photoelectric converter PD may be coupled to the transfer transistor TG which transfers the accumulated charges to the floating diffusion region FD. The floating diffusion region FD is a region that converts charges into a voltage and may cumulatively store charges due to its parasitic capacitance.

An end of the transfer transistor TG may be connected to the photoelectric converter PD, and the other end of the transfer transistor TG may be connected to the floating diffusion region FD. The transfer transistor TG may be a metal oxide semiconductor (MOS) transistor driven by a predetermined bias (e.g., a transfer signal TX). The transfer transistor TG may transfer a first optical signal, which corresponds to charges generated by the photoelectric converter PD, to the floating diffusion region FD according to the transfer signal TX.

The source follower transistor SF may amplify a change in an electric potential of the floating diffusion region FD which receives charges accumulated in the photoelectric converter PD and output the amplified change to an output line Vₒᵤₜ. When the source follower transistor SF is turned on, a predetermined electric potential provided to a drain of the source follower transistor SF, for example, a power supply voltage VDD may be transferred to a drain region of the selection transistor SEL.

The selection transistor SEL may select unit pixel regions to be read on a row-by-row basis. The selection transistor SEL may be a MOS transistor driven by a selection line which applies a predetermined bias (e.g., a row selection signal SX).

The reset transistor RG may periodically reset the floating diffusion region FD. The reset transistor RG may be a MOS transistor driven by a reset line which applies a predetermined bias (e.g., a reset signal RX). When the reset transistor RG is turned on by the reset signal RX, a predetermined electric potential provided to a drain of the reset transistor RG, for example, the power supply voltage VDD may be transferred to the floating diffusion region FD.

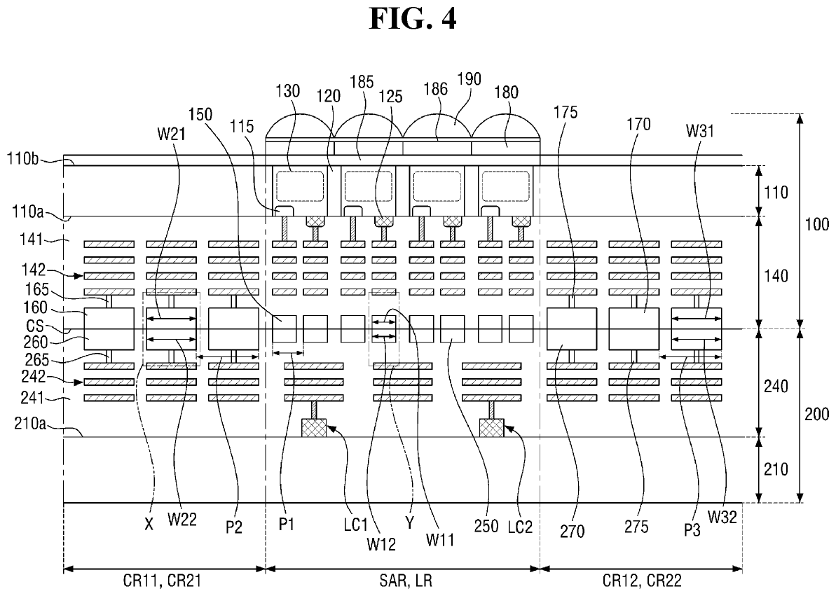

Although the photoelectric converter PD of the pixel circuit has been described above as including a semiconductor photodiode formed on a semiconductor substrate containing silicon or the like, embodiments are not limited to this case. The photoelectric converter PD of the pixel circuit may also include an organic photodiode. In this case, the transfer transistor TG may be omitted. Furthermore, although the photoelectric converter PD is illustrated as a semiconductor photodiode in FIG. 4 to be described later, it may also be an organic photodiode.

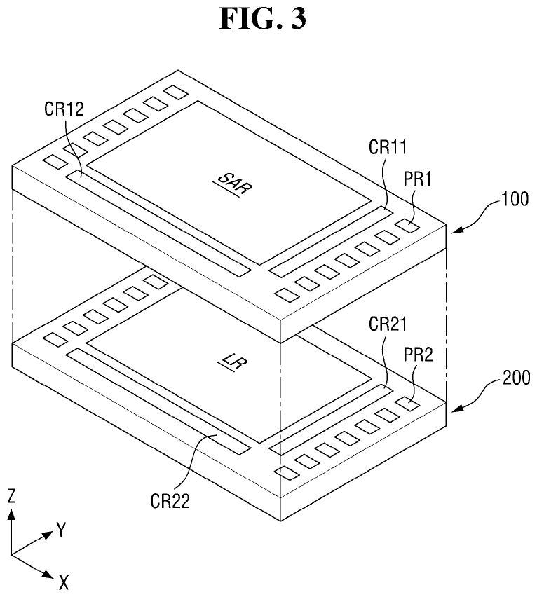

FIG. 3 is a schematic layout view of the image sensor according to the embodiments. Referring to FIG. 3, the image sensor according to the embodiments may include a first substrate structure 100 and a second substrate structure 200. The first substrate structure 100 and the second substrate structure 200 may be stacked in a first direction Z. The first substrate structure 100 may include a pixel region SAR, a (1_1)^{th} connection region CR11, a (1_2)^{th} connection region CR12, and a first pad region PR1.

The pixel region SAR may include a plurality of unit pixels arranged in a matrix. The pixel region SAR may be the APS array 10 of FIG. 1. Each pixel may be composed of a photoelectric converter and transistors. The (1_1)^{th} connection region CR11 and the (1_2)^{th} connection region CR12 may be formed adjacent to the pixel region SAR. The (1_1)^{th} connection region CR11 and the (1_2)^{th} connection region CR12 may electrically connect the pixel region SAR and a logic circuit region LR of the second substrate structure 200. Each of the (1_1)^{th} connection region CR11 and the (1_2)^{th} connection region CR12 is illustrated as being disposed on a side of the pixel region SAR, but embodiments are not limited to this case.

The first pad region PR1 may include a plurality of pads. The first pad region PR1 may be disposed around the pixel region SAR. The pads may be configured to transmit and receive electrical signals to and from an external device. The first pad region PR1 is illustrated as being disposed on two facing sides out of four sides of the pixel region SAR, but embodiments are not limited to this case.

The second substrate structure 200 may include the logic circuit region LR, a (2_1)^{th} connection region CR21, a (2_2)^{th} connection region CR22, and a second pad region PR2.

The logic circuit region LR may include logic circuits including a plurality of transistors. The logic circuit region LR may be electrically connected to the pixel region SAR to provide a predetermined signal to each unit pixel of the pixel region SAR or to control an output signal. The logic circuit region LR may include regions corresponding to the row decoder 20, the row driver 30, the column decoder 40, the timing generator 50, the CDS 60, the ADC 70, and the I/O buffer 80 described above in FIG. 1. That is, the logic circuit region LR may include regions other than the APS array 10 of FIG. 1.

The (2_1)^{th} connection region CR21 and the (2_2)^{th} connection region CR22 may be formed at positions corresponding to the (1_1)^{th} connection region CR11 and the (1_2)^{th} connection region CR12, respectively. The (2_1)^{th} connection region CR21 may be electrically connected to the (1_1)^{th} connection region CR11, and the (2_2)^{th} connection region CR22 may be electrically connected to the (1_2)^{th} connection region CR12.

A part of the logic circuit region LR which corresponds to the row driver 30 (see FIG. 1) may be electrically connected to the pixel region SAR by the (2_1)^{th} connection region CR21 and the (1_1)^{th} connection region CR11. A part of the logic circuit region LR which corresponds to the CDS 60 (see FIG. 1) may be electrically connected to the pixel region SAR by the (2_2)^{th} connection region CR22 and the (1_2)^{th} connection region CR12. The second pad region PR2 may be formed at a position corresponding to the first pad region PR1.

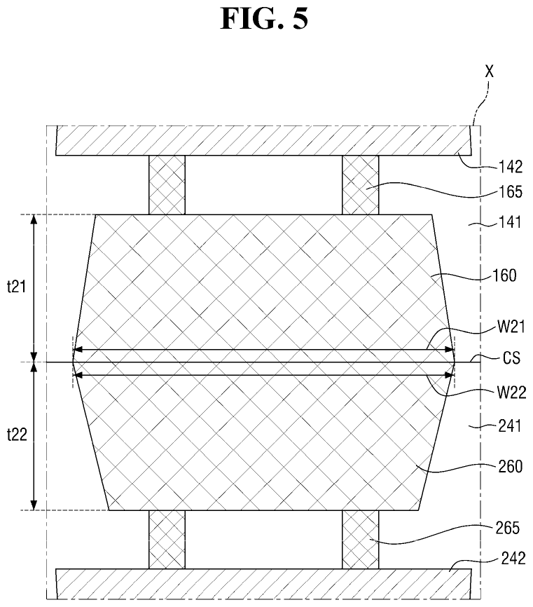

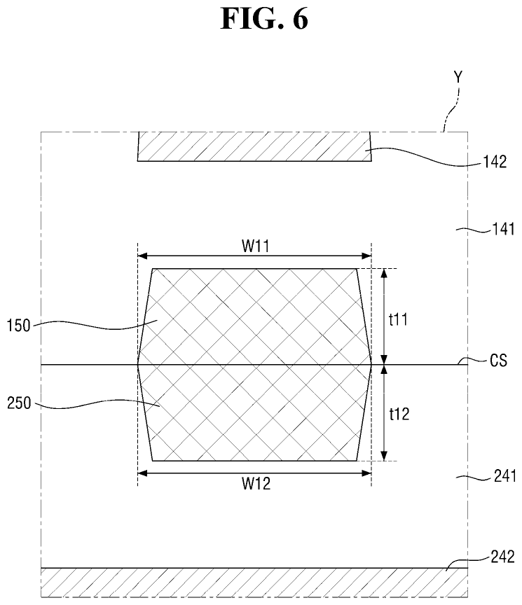

FIG. 4 is a schematic cross-sectional view of an image sensor according to embodiments. FIG. 5 is an enlarged view of portion X of FIG. 4 and FIG. 6 is an enlarged view of portion Y of FIG. 4. For example, a first cross-sectional view of a pixel region SAR and a logic circuit region LR, a second cross-sectional view of a (1_1)^{th} connection region CR11 and a (2_1)^{th} connection region CR21, and a third cross-sectional view of a (1_2)^{th} connection region CR12 and a (2_2)^{th} connection region CR22 may be cross-sectional views taken along a second direction X or along a third direction Y, as shown in FIG. 3. In an alternative example, one of the first through third cross-sectional views may be a cross-sectional view taken along the second direction X, and the others may be cross-sectional views taken along the third direction Y. Alternatively, one of the first through third cross-sectional views may be a cross-sectional view taken along the third direction Y, and the others may be cross-sectional views taken along the second direction X. For reference, an enlarged view of a portion in which a third upper bonding pad 170 and a third lower bonding pad 270 are directly bonded to each other may be substantially the same as FIG. 5.

Referring to FIGS. 4 through 6, the image sensor according to the embodiments may include a first substrate structure 100 and a second substrate structure 200 stacked vertically. The first substrate structure 100 may include a first substrate 110, a first wiring structure 140, color filters 180, and microlenses 190. The second substrate structure 200 may include a second substrate 210 and a second wiring structure 240.

The first substrate 110 may include the pixel region SAR, the (1_1)^{th} connection region CR11, and the (1_2)^{th} connection region CR12 included in the first substrate structure 100. That is, the first substrate 110 may include the pixel region SAR, the (1_1)^{th} connection region CR11, and the (1_2)^{th} connection region CR12. The first substrate 110 may include a first surface 110a and a second surface 110b facing away from each other.

The second substrate 210 may include the logic circuit region LR, the (2_1)^{th} connection region CR21, and the (2_2)^{th} connection region CR22 included in the second substrate structure 200. That is, the second substrate 210 may include the logic circuit region LR, the (2_1)^{th} connection region CR21, and the (2_2)^{th} connection region CR22. The second substrate 210 may include a surface 210a facing away from the first surface 110a of the first substrate 110.

Each of the first substrate 110 and the second substrate 210 may be, for example, bulk silicon substrate or silicon-on-insulator (SOI) substrate. Otherwise, each of the first substrate 110 and the second substrate 210 may be, but is not limited to, a silicon substrate or a substrate made of another semiconductor material such as silicon germanium, silicon germanium on insulator (SGOI), indium antimonide, lead telluride, indium arsenide, indium phosphide, gallium arsenide, or gallium antimonide, for example.

Storage node regions 115, a pixel isolation region 120, and photoelectric converters 130 may be formed in the first substrate 110 of the pixel region SAR. Pixel gate layers 125 may be formed on the first surface 110a of the first substrate 110 of the pixel region SAR. The storage node regions 115 may be formed in the first substrate 110, but may be spaced apart from the photoelectric converters 130. The storage node regions 115 may include impurities of a conductivity type different from that of the first substrate 110. Each of the storage node regions 115 may correspond to the floating diffusion regions FD of FIG. 2, in some embodiments of the invention.

The photoelectric converters 130 (PD in FIG. 2) may be disposed in the first substrate 110. The photoelectric converters 130 may generate photocharges in proportion to the amount of light incident from the outside. Each of the photoelectric converters 130 may receive light and convert an optical signal into an electrical signal. In the image sensor according to the embodiments, each of the photoelectric converters 130 may include a semiconductor photoelectric converter.

The photoelectric converters 130 may be formed by doping the first substrate 110 with impurities. For example, each of the photoelectric converters 160 may have different concentrations of impurities in its upper and lower parts so that it can have a potential slope. For example, each of the photoelectric converters 130 may be formed in a structure in which a plurality of impurity regions are stacked.

The pixel isolation region 120 may surround the photoelectric converters 130. The pixel isolation region 120 is illustrated as extending from the first surface 110a of the first substrate 110 to the second surface 110b of the first substrate 110. However, this is only an example used for ease of description, and embodiments are not limited to this exemplary embodiment. The pixel isolation region 120 may prevent photocharges generated in a specific pixel (due to incident light) from moving to an adjacent pixel region (e.g., due to random drift). In addition, the pixel isolation region 120 may refract light obliquely incident on the photoelectric converters 130. When the first substrate 110 is made of silicon, the pixel isolation region 120 may include, for example, a silicon oxide layer, a silicon nitride layer, an undoped polysilicon layer, air, or a combination of the same.

Each of the pixel gate layers 125 may form a gate electrode of a pixel circuit device disposed in each pixel of the pixel region SAR. Each of the pixel gate layers 125 may be a gate electrode included in one of the transfer transistor TG, the reset transistor RG, the source follower transistor SF, and the selection transistor SEL, as shown by FIG. 2.

A first planarization layer 185 may be formed on the second surface 110b of the first substrate 110. The first planarization layer 185 is illustrated as being formed over the pixel region SAR, the (1_1)^{th} connection region CR11, and the (1_2)^{th} connection region CR12 of the first substrate 110. However, this is only one example that is provided for ease of description, and other exemplary embodiments are not limited to this specific case. That is, the first planarization layer 185 may be disposed in the pixel region SAR of the first substrate 110, and an insulating layer different from the first planarization layer 185 may be formed in the (1_1)^{th} connection region CR11 and the (1_2)^{th} connection region CR12. The first planarization layer 185 may include an insulating material, for example, a silicon oxide layer. Unlike in the drawings, the first planarization layer 185 may be omitted in some cases.

The color filters 180 may be disposed on the first planarization layer 185. The color filters 180 may be disposed above the photoelectric converters 130. In the image sensor according to the embodiments, the color filters 180 may be disposed on the pixel region SAR of the first substrate 110. Each of the color filters 180 may pass light of a specific wavelength so that the light can reach a photoelectric converter 130 disposed under the color filter 180. The color filters 180 may be implemented as a color filter array including at least one of red (R), green (G), and blue (B) filters. Each of the color filters 180 may be made of a material containing a pigment, which is derived from a metal or a metal oxide that is mixed with a resin. A second planarization layer 186 may be disposed on the color filters 180. The second planarization layer 186 may include an electrically insulating material, such as silicon oxide; however, other materials may also be used.

Each of the microlenses 190 may concentrate light into a photoelectric converter 130 by changing a path of light incident on a region other than the photoelectric converter 130. Each of the microlenses 190 may include, but is not limited to, an organic material such as a light transmitting resin.

A first logic circuit gate layer LC1 and a second logic circuit gate layer LC2 may be formed on the surface 210a of the second substrate 210. Unlike in the drawings, the first logic circuit gate layer LC1 and the second logic circuit gate layer LC2 may be at least partially buried in the second substrate 210. Each of the first logic circuit gate layer LC1 and the second logic circuit gate layer LC2 may be included in a logic transistor. The logic transistor may be included in a logic circuit, which provides a predetermined signal to each unit pixel of the pixel region SAR or controls an output signal.

The first wiring structure 140 may be disposed on the first surface 110a of the first substrate 110. The first wiring structure 140 may include a first wiring insulating layer 141, first connection wirings 142, first upper bonding pads 150, second upper bonding pads 160, and third upper bonding pads 170, as shown. The first wiring structure 140 may be formed over the pixel region SAR, the (1_1)^{th} connection region CR11, and the (1_2)^{th} connection region CR12 of the first substrate structure 100. The first connection wirings 142 may be disposed over the pixel region SAR, the (1_1)^{th} connection region CR11, and the (1_2)^{th} connection region CR12. The first upper bonding pads 150 may be included in the pixel region SAR, the second upper bonding pads 160 may be included in the (1_1)^{th} connection region CR11, and the third upper bonding pads 170 may be included in the (1_2)^{th} connection region CR12.

In other words, the first upper bonding pads 150 may overlap the pixel region SAR of the first substrate 110, the second upper bonding pads 160 may overlap the (1_1)^{th} connection region CR11 of the first substrate 110, and the third upper bonding pads 170 may overlap the (1_2)^{th} connection region CR12 of the first substrate 110.

The first wiring insulating layer 141 may be formed on the first surface 110a of the first substrate 110. The pixel gate layers 125 may be disposed in the first wiring insulating layer 141. The first wiring insulating layer 141 may include at least one of an electrically insulating material, such as silicon oxide, silicon nitride, silicon oxynitride, or a low-k material having a lower dielectric constant relative to silicon oxide. The low-k material may include at least one of (but is not limited to): flowable oxide (FOX), torene silazen (TOSZ), undoped silica glass (USG), borosilica glass (BSG), phosphosilica glass (PSG), borophosphosilica glass (BPSG), plasma enhanced tetraethylorthosilicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SiLK, polyimide, a porous polymeric material, and combinations of these materials.

The first connection wirings 142 may be disposed in the first wiring insulating layer 141. The first connection wirings 142 may be electrically connected to the storage node regions 115, the photoelectric converters 130, and the pixel gate layers 125. Each of the first connection wirings 142 may include a wiring barrier layer and a wiring filling layer. The wiring barrier layer may include at least one of, e.g., tantalum (Ta), tantalum nitride (TaN), titanium (Ti), titanium nitride (TiN), ruthenium (Ru), cobalt (Co), nickel (Ni), nickel boron (NiB), tungsten (W), tungsten nitride (WN), zirconium (Zr), zirconium nitride (ZrN), vanadium (V), vanadium nitride (VN), niobium (Nb), niobium nitride (NbN), platinum (Pt), iridium (Ir), and rhodium (Rh). The wiring filling layer may include at least one of, e.g., aluminum (Al), copper (Cu), tungsten (W), cobalt (Co), ruthenium (Ru), and molybdenum (Mo).

The first upper bonding pads 150 may not be connected to the first connection wirings 142. On the other hand, the second upper bonding pads 160 and the third upper bonding pads 170 may be connected to the first connection wirings 142, respectively. The second upper bonding pads 160 may be connected to the first connection wirings 142 by first upper bonding pad vias 165. The third upper bonding pads 170 may be connected to the first connection wirings 142 by second upper bonding pad vias 175. The first upper bonding pads 150 do not necessarily electrically connect the pixel region SAR of the first substrate structure 100 and the logic circuit region LR of the second substrate structure 200. In other words, the first upper bonding pads 150 may be “dummy” bonding pads. The second upper bonding pads 160 and the third upper bonding pads 170 electrically connect the pixel region SAR of the first substrate structure 100 and the logic circuit region LR of the second substrate structure 200. In other words, the second upper bonding pads 160 and the third upper bonding pads 170 may be active bonding pads, in some embodiments of the invention.

Each of the first through third upper bonding pads 150, 160 and 170 and the first and second upper bonding pad vias 165 and 175 may include a pad barrier layer and a pad filling layer. The pad barrier layer may include at least one material selected from a group consisting of tantalum (Ta), tantalum nitride (TaN), titanium (Ti), titanium nitride (TiN), ruthenium (Ru), cobalt (Co), nickel (Ni), nickel boron (NiB), tungsten (W), tungsten nitride (WN), zirconium (Zr), zirconium nitride (ZrN), vanadium (V), vanadium nitride (VN), niobium (Nb), niobium nitride (NbN), platinum (Pt), iridium (Ir), and rhodium (Rh). The pad filling layer may include, for example, copper (Cu).

The second wiring structure 240 may be disposed on the surface 210a of the second substrate 210. The second wiring structure 240 may include a second wiring insulating layer 241, second connection wirings 242, first lower bonding pads 250, second lower bonding pads 260, and third lower bonding pads 270. The first substrate structure 100 and the second substrate structure 200 may be directly bonded by the first wiring structure 140 and the second wiring structure 240. A bonding interface CS, at which the first substrate structure 100 and the second substrate structure 200 are directly bonded to each other, may be defined between the first wiring structure 140 and the second wiring structure 240.

The second wiring structure 240 may be formed over the logic circuit region LR, the (2_1)^{th} connection region CR21, and the (2_2)^{th} connection region CR22 of the second substrate structure 200. And, the second connection wirings 242 may be disposed over the logic circuit region LR, the (2_1)^{th} connection region CR21, and the (2_2)^{th} connection region CR22. The first lower bonding pads 250 may be included in the logic circuit region LR, the second lower bonding pads 260 may be included in the (2_1)^{th} connection region CR21, and the third lower bonding pads 270 may be included in the (2_2)^{th} connection region CR22.

In other words, the first lower bonding pads 250 may overlap the logic circuit region LR of the second substrate 210, the second lower bonding pads 260 may overlap the (2_1)^{th} connection region CR21 of the second substrate 210, and the third lower bonding pads 270 may overlap the (2_2)^{th} connection region CR22 of the second substrate 210.

The second wiring insulating layer 241 may be formed on the surface 210a of the second substrate 210. The first logic circuit gate layer LC1 and the second logic circuit gate layer LC2 may be disposed in the second wiring insulating layer 241. The second wiring insulating layer 241 may include at least one material selected from a group consisting of silicon oxide, silicon nitride, silicon oxynitride, and other low-k materials having a lower dielectric constant relative to silicon oxide.

The second connection wirings 242 may be disposed in the second wiring insulating layer 241. The second connection wirings 242 may be electrically connected to the first logic circuit gate layer LC1 and the second logic circuit gate layer LC2. Each of the second connection wirings 242 may include a wiring barrier layer and a wiring filling layer.

The first lower bonding pads 250 may not be connected to the second connection wirings 242. On the other hand, the second lower bonding pads 260 and the third lower bonding pads 270 may be connected to the second connection wirings 242, respectively. The second lower bonding pads 260 may be connected to the second connection wirings 242 by first lower bonding pad vias 265. The third lower bonding pads 270 may be connected to the second connection wirings 242 by second lower bonding pad vias 275. The first lower bonding pads 250 do not electrically connect the pixel region SAR of the first substrate structure 100 and the logic circuit region LR of the second substrate structure 200. In other words, the first lower bonding pads 250 may be dummy bonding pads. The second lower bonding pads 260 and the third lower bonding pads 270 electrically connect the pixel region SAR of the first substrate structure 100 and the logic circuit region LR of the second substrate structure 200. Thus, the second lower bonding pads 260 and the third lower bonding pads 270 may be active bonding pads.

Each of the first through third lower bonding pads 250, 260 and 270 and the first and second lower bonding pad vias 265 and 275 may include a pad barrier layer and a pad filling layer. The first upper bonding pads 150 may be directly connected to the first lower bonding pads 250. For example, the first upper bonding pads 150 may be directly bonded to the first lower bonding pads 250. The second upper bonding pads 160 may be directly connected to the second lower bonding pads 260, and the third upper bonding pads 170 may be directly connected to the third lower bonding pads 270.

Adjacent first upper bonding pads 150 and adjacent first lower bonding pads 250 may be spaced apart from each other by a first pitch P1. Adjacent second upper bonding pads 160 and adjacent second lower bonding pads 260 may be spaced apart from each other by a second pitch P2. Adjacent third upper bonding pads 170 and adjacent third lower bonding pads 270 may be spaced apart from each other by a third pitch P3. Here, a pitch may be a distance measured based on the bonding interface CS. For example, the second pitch P2 and the third pitch P3 are greater than the first pitch P1. In the image sensor according to the embodiments of the invention, the second pitch P2 may be equal to the third pitch P3; however, other dimensions may also be possible.

A width W11 of each of the first upper bonding pads 150 is smaller than a width W21 of each of the second upper bonding pads 160. The width W11 of each of the first upper bonding pads 150 is smaller than a width W31 of each of the third upper bonding pads 170. Here, a width may be measured based on the bonding interface CS.

In the image sensor according to the embodiments, the width W21 of each of the second upper bonding pads 160 may be the same as the width W31 of each of the third upper bonding pads 170. Here, “the same width” is intended to encompass not only the completely same width at two positions being compared but also a minute difference in width caused by a process margin or the like.

A width W12 of each of the first lower bonding pads 250 is smaller than a width W22 of each of the second lower bonding pads 260. The width W12 of each of the first lower bonding pads 250 is smaller than a width W32 of each of the third lower bonding pads 270. The width W22 of each of the second lower bonding pads 260 may be the same as the width W32 of each of the third lower bonding pads 270. For example, the width W11 of each of the first upper bonding pads 150 may be the same as the width W12 of each of the first lower bonding pads 250. The width W21 of each of the second upper bonding pads 160 may be the same as the width W22 of each of the second lower bonding pads 260. The width W31 of each of the third upper bonding pads 170 may be the same as the width W32 of each of the third lower bonding pads 270.

In the image sensor according to the embodiments, the first upper bonding pads 150 may be aligned with the first lower bonding pads 250 and matched with the first lower bonding pads 250. The second upper bonding pads 160 may be aligned with the second lower bonding pads 260 and matched with the second lower bonding pads 260. The third upper bonding pads 170 may be aligned with the third lower bonding pads 270 and matched with the third lower bonding pads 270.

A thickness t11 of each of the first upper bonding pads 150 is smaller than a thickness t21 of each of the second upper bonding pads 160. A thickness of each of the third upper bonding pads 170 may be the same as the thickness t21 of each of the second upper bonding pads 160. As used herein, the phrase “the same thickness” is intended to encompass not only the completely same thickness at two positions being compared but also a minute difference in thickness caused by a process margin or the like. In addition, a thickness may be measured based on the bonding interface CS.

A thickness t12 of each of the first lower bonding pads 250 is smaller than a thickness t22 of each of the second lower bonding pads 260. A thickness of each of the third lower bonding pads 270 may be the same as the thickness t22 of each of the second lower bonding pads 260.

In the image sensor according to the embodiments, the thickness t11 of each of the first upper bonding pads 150 may be the same as the thickness t12 of each of the first lower bonding pads 250. The thickness t21 of each of the second upper bonding pads 160 may be the same as the thickness t22 of each of the second lower bonding pads 260.

The width W12 of each of the first lower bonding pads 250 is smaller than the width W22 of each of the second lower bonding pads 260. In addition, it is assumed that the thicknesses (t11+t12) of the first lower and upper bonding pads 250 and 150 directly bonded to each other are the same as the thicknesses (t21+t22) of the second lower and upper bonding pads 260 and 160 directly bonded to each other.

In this case, stress generated at bonding surfaces between the first lower bonding pads 250 and the first upper bonding pads 150 is greater than stress generated at bonding surfaces between the second lower bonding pads 260 and the second upper bonding pads 160. That is, stress is more concentrated on the bonding surfaces between the first lower bonding pads 250 and the first upper bonding pads 150 than on the bonding surfaces between the second lower bonding pads 260 and the second upper bonding pads 160. This increases the probability that the first lower bonding pads 250 will be separated from the first upper bonding pads 150 at the bonding surfaces between the first lower bonding pads 250 and the first upper bonding pads 150.

In addition, it is assumed that the thicknesses (t11+t12) of the first lower and upper bonding pads 250 and 150 directly bonded to each other are smaller than the thicknesses (t21+t22) of the second lower and upper bonding pads 260 and 160 directly bonded to each other. In this case, as the thicknesses (t11+t12) of the first lower and upper bonding pads 250 and 150 directly bonded to each other are reduced, stress generated at the bonding surfaces between the first lower bonding pads 250 and the first upper bonding pads 150 may also be reduced. Therefore, the reliability of bonding pads directly bonded to each other can be improved by adjusting thicknesses of the bonding pads according to widths of the bonding pads directly bonded to each other.

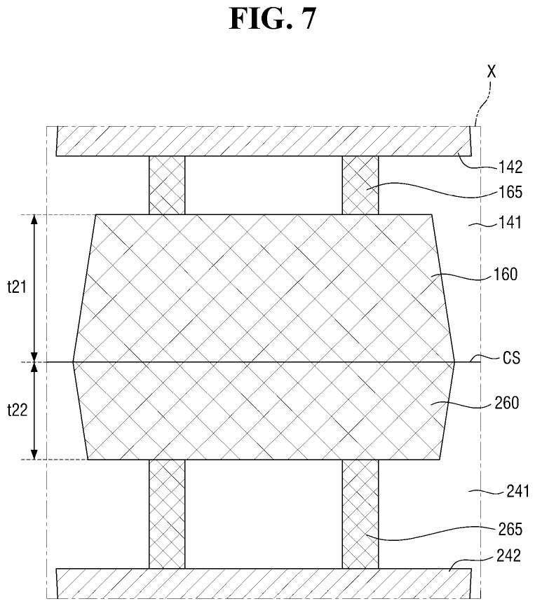

FIG. 7 illustrates an image sensor according to embodiments. For ease of description, differences from elements and features described using FIGS. 4 through 6 will be mainly described below. For reference, FIG. 7 is an enlarged view of portion X of FIG. 4. Referring to FIG. 7, in the image sensor according to the embodiments, a thickness t12 of a first lower bonding pad 250 may be the same as a thickness t22 of a second lower bonding pad 260. A thickness of a third lower bonding pad 270 may be the same as the thickness t12 of the first lower bonding pad 250. A thickness t21 of a second upper bonding pad 160 is greater than the thickness t22 of the second lower bonding pad 260. Contrary to the illustration in the drawing, the thickness t21 of the second upper bonding pad 160 may be smaller than the thickness t22 of the second lower bonding pad 260. Here, a thickness t11 of a first upper bonding pad 150 may be the same as the thickness t21 of the second upper bonding pad 160.

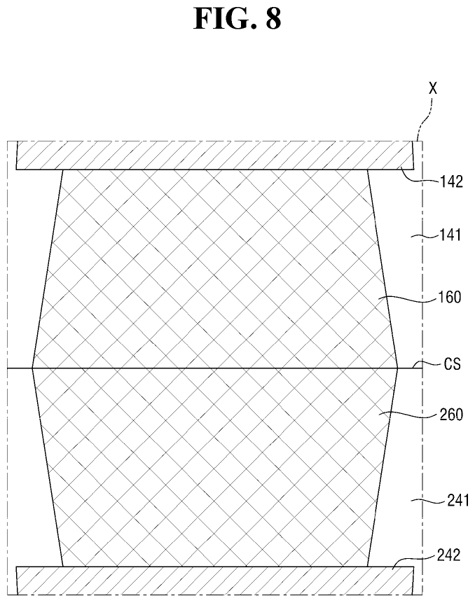

FIG. 8 illustrates an image sensor according to embodiments. For ease of description, differences from elements and features described using FIGS. 4 through 6 will be mainly described below. For reference, FIG. 8 is an enlarged view of portion X of FIG. 4. Referring to FIG. 8, in the image sensor according to the embodiments, a second upper bonding pad 160 may be directly connected to a first connection wiring 142. A second lower bonding pad 260 may be directly connected to a second connection wiring 242. A first upper bonding pad via 165 may not be disposed between the second upper bonding pad 160 and the first connection wiring 142. A first lower bonding pad via 265 may not be disposed between the second lower bonding pad 260 and the second connection wiring 242. Unlike in the drawing, the first upper bonding pad via 165 may not be formed, and the first lower bonding pad via 265 may be formed. Alternatively, the first upper bonding pad via 165 may be formed, and the first lower bonding pad via 265 may not be formed.

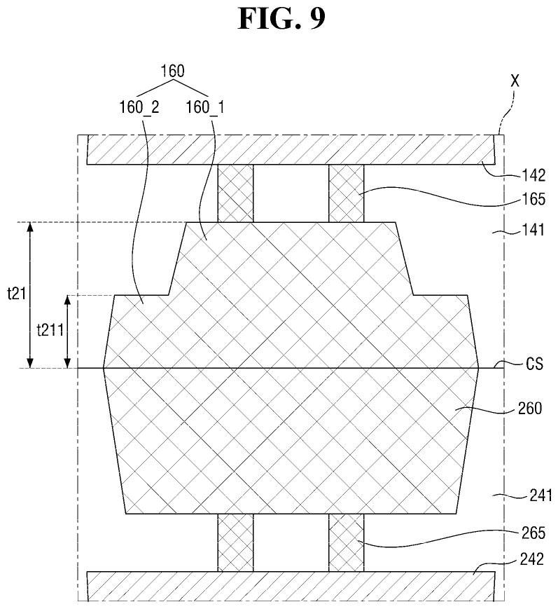

FIG. 9 illustrates an image sensor according to embodiments. For ease of description, differences from elements and features described using FIGS. 4 through 6 will be mainly described below. For reference, FIG. 9 is an enlarged view of portion X of FIG. 4. Referring to FIG. 9, in the image sensor according to the embodiments, a second upper bonding pad 160 may include a first sub-bonding pad 160_1 and a second sub-bonding pad 160_2. The second sub-bonding pad 1602 may be disposed on at least one side of the first sub-bonding pad 160_1. For example, a thickness t21 of the first sub-bonding pad 160_1 is greater than a thickness t211 of the second sub-bonding pad 160_2. Unlike in the drawing, a second lower bonding pad 260 may have a shape corresponding to that of the second upper bonding pad 160. Alternatively, unlike in the drawing, the second lower bonding pad 260 may have the same shape as the second upper bonding pad 160 of FIG. 9, and the second upper bonding pad 160 may have the same shape as the second lower bonding pad 260 of FIG. 9.

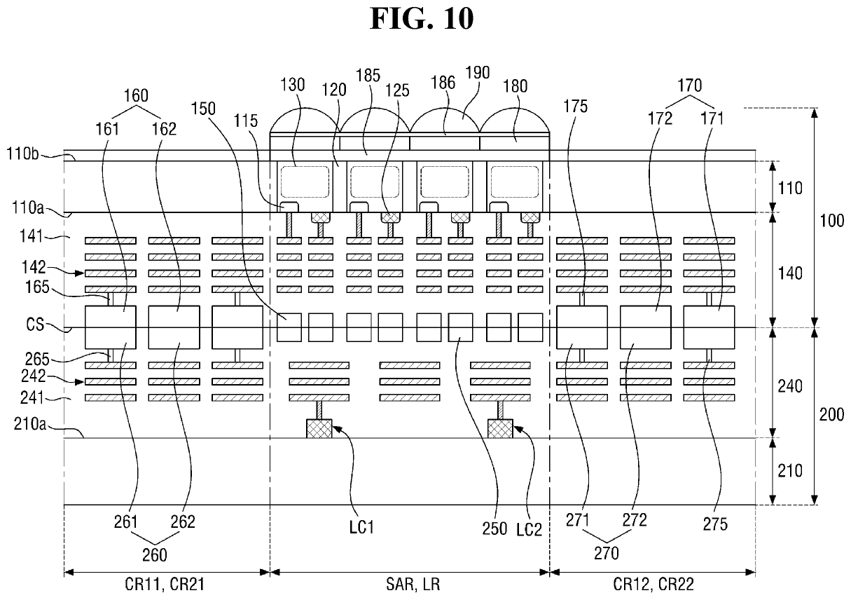

FIG. 10 illustrates an image sensor according to embodiments. For ease of description, differences from elements and features described above with reference to FIGS. 4 through 6 will be mainly described below. Referring to FIG. 10, in the image sensor according to the embodiments, second upper bonding pads 160 may include (2_1)^{th} upper bonding pads 161 and (2_2)^{th} upper bonding pads 162. Third upper bonding pads 170 may include (3_1)^{th} upper bonding pads 171 and (3_2)^{th} upper bonding pads 172. Second lower bonding pads 260 may include (2_1)^{th} lower bonding pads 261 and (2_2)^{th} lower bonding pads 262. Third lower bonding pads 270 may include (3_1)^{th} lower bonding pads 271 and (3_2)^{th} lower bonding pads 272.

The (2_1)^{th} upper bonding pads 161 and the (3_1)^{th} upper bonding pads 171 may be connected to first connection wirings 142. The (2_1)^{th} lower bonding pads 261 and the (3_1)^{th} lower bonding pads 271 may be connected to second connection wirings 242. The (2_2)^{th} upper bonding pads 162 and the (3_2)^{th} upper bonding pads 172 are not connected to the first connection wirings 142. The (2_2)^{th} lower bonding pads 262 and the (3_2)^{th} lower bonding pads 272 are not connected to the second connection wirings 242. The (2_1)^{th} upper bonding pads 161, the (3_1)^{th} upper bonding pads 171, the (2_1)^{th} lower bonding pads 261, and the (3_1)^{th} lower bonding pads 271 may be active bonding pads which electrically connect a pixel region SAR of a first substrate structure 100 and a logic circuit region LR of a second substrate structure 200. The (2_2)^{th} upper bonding pads 162, the (3_2)^{th} upper bonding pads 172, the (2_2)^{th} lower bonding pads 262 and the (3_2)^{th} lower bonding pads 272 may be dummy bonding pads which do not electrically connect the pixel region SAR of the first substrate structure 100 and the logic circuit region LR of the second substrate structure 200.

A width of each of the (2_1)^{th} upper bonding pads 161 may be the same as a width of each of the (2_2)^{th} upper bonding pads 162, and a width of each of the (3_1)^{th} upper bonding pads 171 may be the same as a width of each of the (3_2)^{th} upper bonding pads 172. Unlike in the drawing, either the second upper bonding pads 160 or the third upper bonding pads 170 may not include dummy bonding pads. Either the second lower bonding pads 260 or the third lower bonding pads 270 may not include dummy bonding pads. In addition, unlike in the drawing, the (2_2)^{th} upper bonding pads 162 may not be connected to the first connection wirings 142, and the (2_2)^{th} lower bonding pads 262 may be connected to the second connection wirings 242. Conversely, the (2_2)^{th} upper bonding pads 162 may be connected to the first connection wirings 142, and the (2_2)^{th} lower bonding pads 262 may not be connected to the second connection wirings 242. Likewise, the (3_2)^{th} upper bonding pads 172 may not be connected to the first connection wirings 142, and the (3_2)^{th} lower bonding pads 272 may be connected to the second connection wirings 242. And the (3_2)^{th} upper bonding pads 172 may be connected to the first connection wirings 142, and the (3_2)^{th} lower bonding pads 272 may not be connected to the second connection wirings 242.

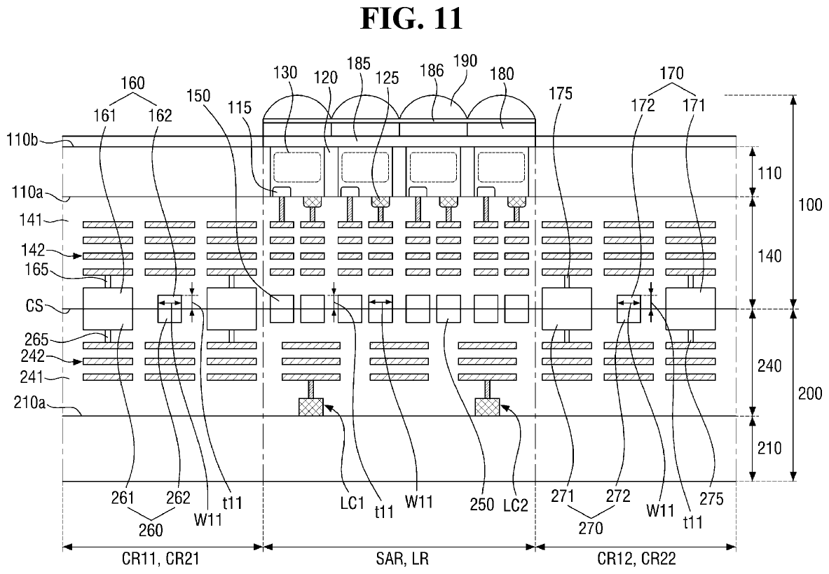

FIG. 11 illustrates an image sensor according to embodiments. For ease of description, differences from elements and features described using FIG. 10 will be mainly described below. Referring to FIG. 11, in the image sensor according to the embodiments, a width of each of (2_1)^{th} upper bonding pads 161 is greater than a width of each of (2_2)^{th} upper bonding pads 162, and a width of each of (3_1)^{th} upper bonding pads 171 is greater than a width of each of (3_2)^{th} upper bonding pads 172. The width of each of the (2_2)^{th} upper bonding pads 162 and the width of each of the (3_2)^{th} upper bonding pads 172 may be the same as a width W11 of each of first upper bonding pads 150.

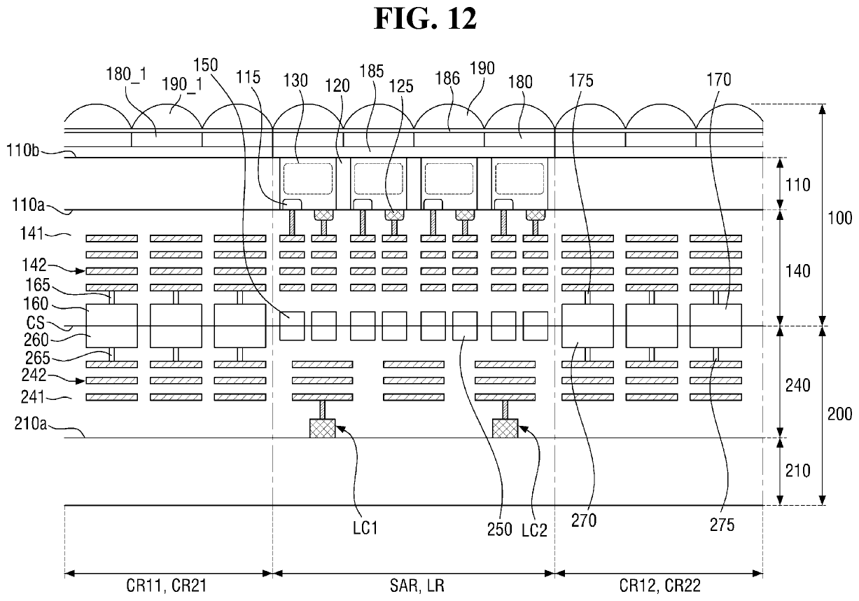

FIG. 12 illustrates an image sensor according to embodiments. For ease of description, differences from elements and features described using FIGS. 4 through 6 will be mainly described below. Referring to FIG. 12, in the image sensor according to the embodiments, a (1_1)^{th} connection region CR11 may include dummy color filters 180_1 and dummy microlenses 190_1. A (1_2)^{th} connection region CR12 may also include dummy color filters 180_1 and dummy microlenses 190_1.

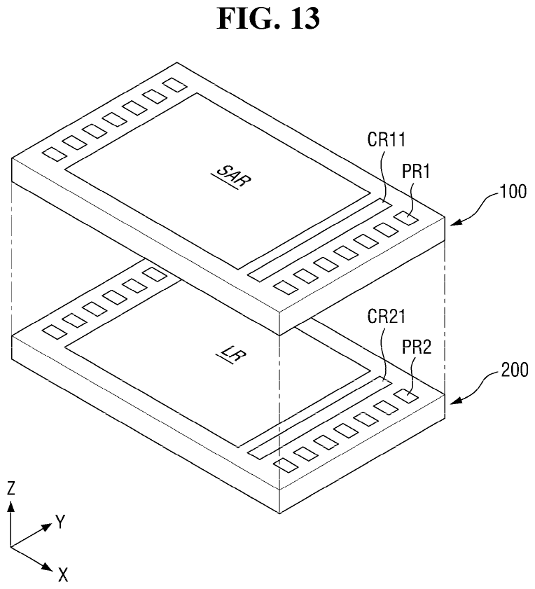

FIG. 13 is a schematic layout view of an image sensor according to embodiments. For ease of description, differences from elements and features described using FIG. 3 will be mainly described below. Referring to FIG. 13, in the image sensor according to the embodiments, a first substrate structure 100 may include a pixel region SAR, a (1_1)^{th} connection region CR11, and a first pad region PR1. A second substrate structure 200 may include a logic circuit region LR, a (2_1)^{th} connection region CR21, and a second pad region PR2.

A part of the logic circuit region LR which corresponds to a row driver 30 (see FIG. 1) may be electrically connected to the pixel region SAR by the (2_1)^{th} connection region CR21 and the (1_1)^{th} connection region CR11. However, a part of the logic circuit region LR which corresponds to a CDS 60 (see FIG. 1) may be electrically connected to the pixel region SAR at a position overlapping the pixel region SAR.

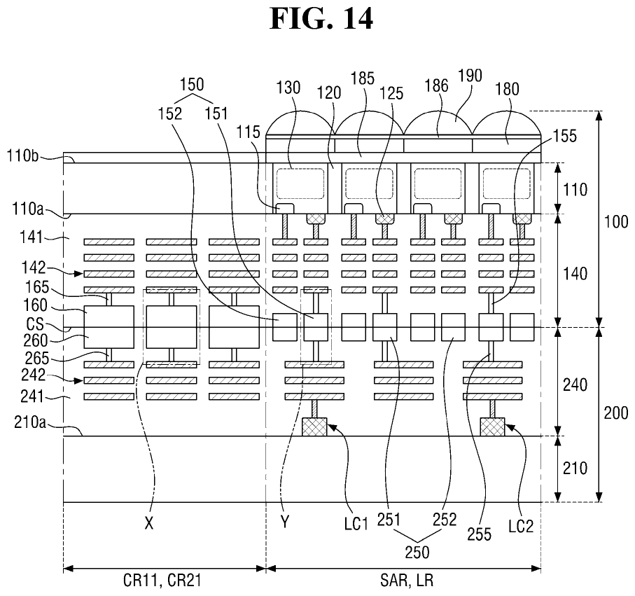

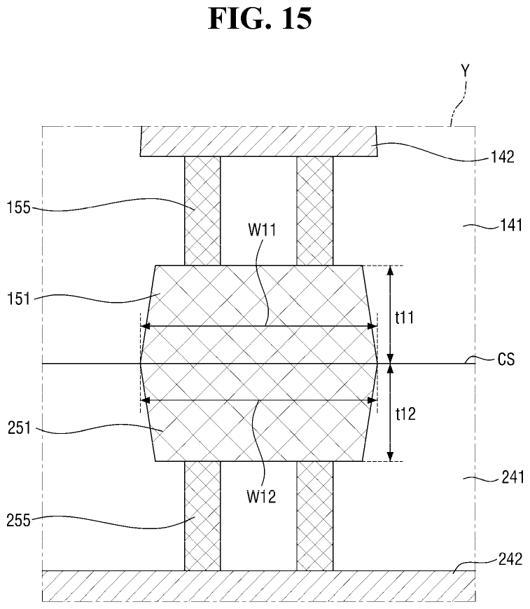

FIG. 14 is a schematic cross-sectional view of an image sensor according to the embodiments. FIG. 15 is an enlarged view of portion Y of FIG. 14. For ease of description, differences from elements and features described using FIGS. 4 through 6 will be mainly described below. For reference, a description of an enlarged view of portion X of FIG. 14 may be substantially the same as the description given using one of FIGS. 5 and 7 through 9.

For example, a first cross-sectional view of a pixel region SAR and a logic circuit region LR and a second cross-sectional view of a (1_1)^{th} connection region CR11 and a (2_1)^{th} connection region CR21 may be cross-sectional views taken along the second direction X or along the third direction Y. An another example, the first cross-sectional view may be a cross-sectional view taken along the second direction X, and the second cross-sectional view may be a cross-sectional view taken along the third direction Y. Alternatively, the first cross-sectional view may be a cross-sectional view taken along the third direction Y, and the second cross-sectional view may be a cross-sectional view taken along the second direction X.

Referring to FIGS. 14 and 15, in the image sensor according to the embodiments, first upper bonding pads 150 may include (1_1)^{th} upper bonding pads 151 and (1_2)^{th} upper bonding pads 152. First lower bonding pads 250 may include (1_1)^{th} lower bonding pads 251 and (1_2)^{th} lower bonding pads 252. The first upper bonding pads 150 may be connected to first connection wirings 142. For example, the (1_1)^{th} upper bonding pads 151 may be connected to the first connection wirings 142 by third upper bonding pad vias 155. The (1_2)^{th} upper bonding pads 152 are not connected to the first connection wirings 142. The first lower bonding pads 250 may be connected to second connection wirings 242. For example, the (1_1)^{th} lower bonding pads 251 may be connected to the second connection wirings 242 by third lower bonding pad vias 255. The (1_2)^{th} lower bonding pads 252 are not connected to the second connection wirings 242. The (1_1)^{th} upper bonding pads 151 and the (1_1)^{th} lower bonding pads 251 may be active bonding pads which electrically connect the pixel region SAR of a first substrate structure 100 and the logic circuit region LR of a second substrate structure 200. The (1_2)^{th} upper bonding pads 152 and the (1_2)^{th} lower bonding pads 252 may be dummy bonding pads which do not electrically connect the pixel region SAR of the first substrate structure 100 and the logic circuit region LR of the second substrate structure 200.

A width W11 of each of the (1_1)^{th} upper bonding pads 151 may be the same as a width of each of the (1_2)^{th} upper bonding pads 152. A width W12 of each of the (1_1)^{th} lower bonding pads 251 may be the same as a width of each of the (1_2)^{th} lower bonding pads 252. The width W11 of each of the (1_1)^{th} upper bonding pads 151 may be the same as the width W12 of each of the (1_1)^{th} lower bonding pads 251. A thickness t11 of each of the (1_1)^{th} upper bonding pads 151 may be the same as a thickness t12 of each of the (1_1)^{th} lower bonding pads 251.

In FIG. 14, the first upper bonding pads 150 and the first lower bonding pads 250 include active bonding pads and dummy bonding pads. However, embodiments are not limited to this case. That is, the first upper bonding pads 150 and the first lower bonding pads 250 may include only active bonding pads, in some embodiments of the invention. Furthermore, unlike in the drawing, the second upper bonding pads 160 and the second lower bonding pads 260 may include not only active bonding pads but also dummy bonding pads. And, when the second upper bonding pads 160 and the second lower bonding pads 260 include dummy bonding pads, a width of each dummy bonding pad may be the same as a width of each active bonding pad, or the width of each dummy bonding pad may be smaller than the width of each active bonding pad as illustrated in FIG. 11.

In concluding the detailed description, those skilled in the art will appreciate that many variations and modifications may be made to the preferred embodiments without substantially departing from the principles of the present inventive concept. Therefore, the disclosed preferred embodiments of the inventive concept are used in a generic and descriptive sense only and not for purposes of limitation.

What is claimed is:

1. An image sensor, comprising:
a first substrate including a pixel region, a first connection wire, a plurality of first type of upper bonding pads including a first upper bonding pad, and a plurality of second type of upper bonding pads including a second upper bonding pad; and
a second substrate including a second connection wire, a plurality of first type of bottom bonding pads including a first bottom bonding pad, and a plurality of second type of bottom bonding pads including a second bottom bonding pad;
wherein the first upper bonding pad has a first surface and a second surface opposite to the first surface;
wherein the second upper bonding pad has a third surface and a fourth surface opposite to the third surface;
wherein the first bottom bonding pad has a fifth surface directly connected to the second surface and a sixth surface opposite to the fifth surface;
wherein the second bottom bonding pad has a seventh surface directly connected to the fourth surface and an eighth surface opposite to the seventh surface;
wherein a width of the second surface in a first direction is greater than a width of the third surface in the first direction;
wherein the first surface is connected to the first connection wire through only single via and the sixth surface is connected to the second connection wire through only single via; and
wherein a height of the first upper bonding pad in a second direction perpendicular to the first direction is greater than a height of the first bottom bonding pad in the second direction.

2. The image sensor of claim 1, wherein the height of the first upper bonding pad in the second direction is greater than a height of the second upper bonding pad in the second direction.

3. The image sensor of claim 2, wherein the first upper bonding pad includes a pad barrier layer and a pad filling layer; wherein the pad barrier layer includes tantalum and the pad filling layer includes copper; and wherein the single via that connects the first upper bonding pad to the first connection wire includes tantalum and copper.

4. The image sensor of claim 3, wherein the height of the first upper bonding pad in the second direction is greater from a height of the second bottom bonding pad in the second direction.

5. The image sensor of claim 4, wherein the height of the first bottom bonding pad in the second direction is different from the height of the second bottom bonding pad in the second direction.

6. The image sensor of claim 5, wherein the plurality of first type of upper bonding pads are spaced apart from each other by a first pitch in the first direction and the plurality of second type of upper bonding pads are spaced apart from each other by a second pitch in the first direction; and wherein the first pitch is different from the second pitch.

7. The image sensor of claim 6, wherein the second upper bonding pad is not directly connected to the first connection wire and the second bottom bonding pad is not directly connected to the second connection wire.

8. The image sensor of claim 7, wherein the second upper bonding pad vertically overlaps with the pixel region in a plan view.

9. The image sensor of claim 8, wherein the first substrate further comprises:
a connection region adjacent to the pixel region; and
wherein the first upper bonding pad vertically overlaps with the connection region in the plan view.

10. An image sensor, comprising:
a first substrate including a pixel region, a plurality of first type of upper bonding pads including a first upper bonding pad, and a plurality of second type of upper bonding pads including a second upper bonding pad; and
a second substrate including a plurality of first type of bottom bonding pads including a first bottom bonding pad, and a plurality of second type of bottom bonding pads including a second bottom bonding pad;
wherein the first upper bonding pad has a first surface;
wherein the second upper bonding pad has a second surface;
wherein the first bottom bonding pad has a third surface directly connected to the first surface;
wherein the second bottom bonding pad has a fourth surface directly connected to the second surface;
wherein a width of the first upper bonding pad in a first direction is greater than a width of the second upper bonding pad in the first direction; and
wherein a width of the first bottom bonding pad in the first direction is greater than a width of the second bottom bonding pad in the first direction.

11. The image sensor of claim 10, wherein the first upper bonding pad includes a pad barrier layer and a pad filling layer; and wherein the pad barrier layer includes tantalum and the pad filling layer includes copper.

12. The image sensor of claim 11, wherein a height of the first upper bonding pad in a second direction perpendicular to the first direction is greater than a height of the first bottom bonding pad in the second direction.

13. The image sensor of claim 11, wherein the plurality of first type of upper bonding pads are spaced apart from each other by a first pitch in the first direction and the plurality of second type of upper bonding pads are spaced apart from each other by a second pitch in the first direction; and wherein the first pitch is greater than the second pitch.

14. The image sensor of claim 12, wherein the plurality of first type of upper bonding pads are spaced apart from each other by a first pitch in the first direction and the plurality of second type of upper bonding pads are spaced apart from each other by a second pitch in the first direction; and wherein the first pitch is greater than the second pitch.

15. The image sensor of claim 14, wherein the second upper bonding pad vertically overlaps with the pixel region in the plan view.

16. The image sensor of claim 15,
wherein the first substrate further comprises a first connection wire, a second connection wire, a third connection wire, and a fourth connection wire;
wherein the second substrate further comprises a fourth connection wire, a fifth connection wire, and a sixth connection wire; and
wherein the first connection wire, the second connection wire, the third connection wire, the fourth connection wire, the first upper bonding pad, the first bottom bonding pad, the fourth connection wire, the fifth connection wire, the sixth connection wire are sequentially arranged in a third direction perpendicular to the first direction.

17. An image sensor comprising:
a first substrate including a pixel region, a first connection wire, a plurality of first type of upper bonding pads including a first upper bonding pad, and a plurality of second type of upper bonding pads including a second upper bonding pad; and
a second substrate including a second connection wire, a plurality of first type of bottom bonding pads including a first bottom bonding pad, and a plurality of second type of bottom bonding pads including a second bottom bonding pad;
wherein the first upper bonding pad has a first surface;
wherein the second upper bonding pad has a second surface;
wherein the first bottom bonding pad has a third surface directly connected to the first surface;
wherein the second bottom bonding pad has a fourth surface directly connected to the second surface;
wherein the first surface is connected to the first connection wire through only single via and the third surface is connected to the second connection wire through only single via; and
wherein a height of the first upper bonding pad in a first direction is greater than a height of the second bottom bonding pad in the first direction.

18. The image sensor of claim 17, wherein the first upper bonding pad includes a pad barrier layer and a pad filling layer; wherein the pad barrier layer includes tantalum and the pad filling layer includes copper; and wherein the single via that connects the first upper bonding pad to the first connection wire includes tantalum and copper.

19. The image sensor of claim 18, wherein the plurality of first type of upper bonding pads are spaced apart from each other by a first pitch in a second direction perpendicular to the first direction and the plurality of second type of upper bonding pads are spaced apart from each other by a second pitch in the second direction; and wherein the first pitch is different from the second pitch.

20. The image sensor of claim 19, wherein a width of the first upper bonding pad in the second direction is different from a width of the second upper bonding pad in the second direction; and wherein a width of the first bottom bonding pad in the second direction is different from a width of the second bottom bonding pad in the second direction.
